(19) United States
(12) Patent Application Publication
(10) Pub. No.: US 2026/0150511 A1
(43) Pub. Date: May 28, 2026

(54) Display Device

(71) Applicant: LG Display Co., Ltd., Seoul (KR)

(72) Inventor: Minsoo Jang, Paju-si (KR)

(21) Appl. No.: 19/344,183

(22) Filed: Sep. 29, 2025

(30) Foreign Application Priority Data
Nov. 28, 2024 (KR) 10-2024-0173321

(51) Int. Cl. H10K 59/122; H10K 59/80

(52) U.S. Cl. CPC H10K 59/122; H10K 59/80515; H10K 59/80521; H10K 59/871; H10K 59/873

(57) ABSTRACT

A display device according to an exemplary embodiment of the present disclosure includes a substrate which is divided into an display area and a non-display area, a planarization layer disposed above the substrate in the display area and extending into the non-display area, an anode disposed on the planarization layer in the display area, a bank including a bank hole exposing a part of the anode, an organic layer disposed on the bank including the bank hole, a cathode disposed on the organic layer and extending into the non-display area, a first step relieving layer disposed on the cathode and filled in the bank hole, an inorganic layer disposed on the first step relieving layer and extending into the non-display area to cover the cathode, and an encapsulating unit disposed above the inorganic layer, thereby minimizing permeation of moisture and oxygen.

### CROSS-REFERENCE TO RELATED APPLICATIONS

This application claims priority under 35 U.S.C. §119(a) to the Republic of Korea Patent Application No. 10-2024-0173321, filed on November 28, 2024, the entire contents of which are hereby expressly incorporated by reference into the present application.

### TECHNICAL FIELD

The present disclosure relates to a display device, and more particularly, to a display device which minimizes permeation of moisture and oxygen.

### BACKGROUND

Currently, as it enters a full-scale information era, a field of a display device which visually expresses electrical information signals has been rapidly developed and studies are continued to improve performances of various display devices such as thin-thickness, lightweight, and low power consumption.

As a representative display device, there are a liquid crystal display device (LCD), an electro-wetting display device (EWD), and an organic light emitting display device (OLED).

Among them, the organic light emitting display device is a self-emitting display device such that a separate light source is not necessary, which is different from the liquid crystal display device. Therefore, the organic light emitting display device may be manufactured to have a lightweight and small thickness. Further, since the organic light emitting display device is advantageous not only in terms of power consumption due to low-voltage driving, but also in terms of color implementation, response speed, viewing angle, and contrast ratio (CR), it attracts attention as a next-generation display device.

However, the organic light emitting display device has a problem in that an organic layer which configures a light emitting diode is vulnerable to heat, moisture, and oxygen.

### SUMMARY

An object to be achieved by the present disclosure is to provide a display device which is capable of minimizing permeation of moisture and oxygen.

Another object to be achieved by the present disclosure is to provide a display device which suppresses cracks of a cathode and an inorganic layer caused by bubbles which are generated when an encapsulation unit is bonded.

Another object to be achieved by the present disclosure is to provide a display device with an improved light extraction efficiency.

Objects of the present disclosure are not limited to the above-mentioned objects, and other objects, which are not mentioned above, can be clearly understood by those skilled in the art from the following descriptions.

In order to achieve the objects as described above, according to an aspect of the present disclosure, a display device may include a substrate which is divided into an display area and a non-display area, a planarization layer disposed above the substrate in the display area and extending into the non-display area, an anode disposed on the planarization layer in the display area,a bank including a bank hole exposing a part of the anode, an organic layer disposed on the bank including the bank hole, a cathode disposed on the organic layer and extending into the non-display area, a first step relieving layer disposed on the cathode and filled in the bank hole, an inorganic layer disposed on the first step relieving layer and extending into the non-display area to cover the cathode and an encapsulation unit disposed above the inorganic layer.

Other detailed matters of the exemplary embodiments are included in the detailed description and the drawings.

According to the present disclosure, a trench pattern is formed in an edge of a non-display area to minimize permeation of moisture and oxygen.

According to the present disclosure, a step relieving layer is disposed between a cathode of an emission area and an inorganic layer to remove the step caused by the taper of the bank, thereby minimizing permeation of moisture and oxygen to the light emitting diode. According to the present disclosure, a step relieving layer is disposed on a side surface of a trench pattern to block permeation of moisture and oxygen into the display device, thereby improving a lifespan and a reliability of the display device.

According to the present disclosure, a plurality of concave portions is formed on a surface of a planarization layer to improve a light extraction efficiency, thereby implementing the low power. Further, it is possible to implement ESG (Environment/Social/Governance) by reducing greenhouse gas emissions by reducing the use of fossil fuels for power generation.

The effects according to the present disclosure are not limited to the contents exemplified above, and more various effects are included in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a plan view schematically illustrating a display device according to a first exemplary embodiment of the present disclosure.

FIG. 2 is a cross-sectional view taken along the line A-A' of FIG. 1.

FIG. 3 is a cross-sectional view taken along the line B-B’ of FIG. 1.

FIG. 4 is a plan view schematically illustrating a display device according to a second exemplary embodiment of the present disclosure.

FIG. 5 is a cross-sectional view taken along the line C-C' of FIG. 4.

FIG. 6 is a cross-sectional view schematically illustrating a display device according to a third exemplary embodiment of the present disclosure.

FIG. 7 is a plan view schematically illustrating a display device according to a fourth exemplary embodiment of the present disclosure.

FIG. 8 is a cross-sectional view taken along the line D-D' of FIG. 7.

FIG. 9 is a cross-sectional view taken along the line E-E' of FIG. 7.

FIG. 10 is a cross-sectional view schematically illustrating a display device according to a fifth exemplary embodiment of the present disclosure.

FIG. 11 is a cross-sectional view schematically illustrating a display device according to a sixth exemplary embodiment of the present disclosure.

FIG. 12 is a plan view schematically illustrating a display device according to a seventh exemplary embodiment of the present disclosure.

FIG. 13 is a cross-sectional view taken along the line F-F' of FIG. 12.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, an exemplary embodiment of the present disclosure will be described in detail with reference to the drawings.

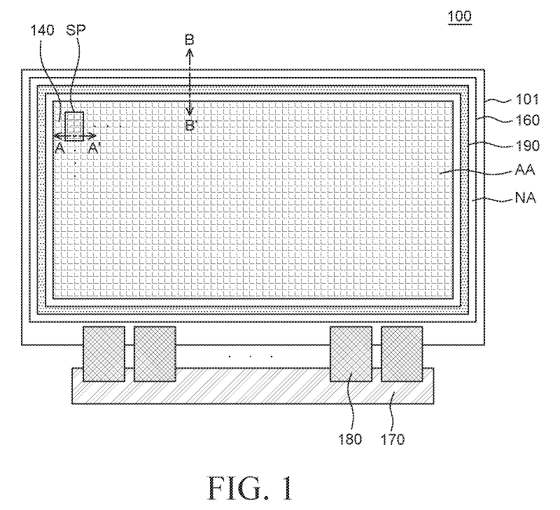

FIG. 1 is a plan view schematically illustrating a display device according to a first exemplary embodiment of the present disclosure.

Referring to FIG. 1, a display device 100 according to a first exemplary embodiment of the present disclosure may include a display panel, a flexible film 180, a printed circuit board 170, and a trench pattern 190.

The display panel is a panel for displaying images to the user.

The display panel may be simply configured by a substrate 101 and an encapsulation unit including a sealing member above the substrate 101 and a reinforcement substrate 160.

The display panel may include a display element which displays images, a driving element which drives the display element, and wiring lines which transmit various signals to the display element and the driving element. The display element may be defined in different ways depending on a type of the display panel. For example, when the display panel is an organic light emitting display panel, the display element may be an organic light emitting diode which includes an anode, an organic light emitting layer, and a cathode. For example, when the display panel is a liquid crystal display panel, the display element may be a liquid crystal display element.

Hereinafter, even though the display panel is assumed as an organic light emitting display panel, the display panel is not limited to the organic light emitting display panel.

The display panel may include an display area AA and a non-display area NA.

The display area AA is an area where images are displayed in the display panel.

In the display area AA, a plurality of sub pixels SP which configures a plurality of pixels and a circuit for driving the plurality of sub pixels SP may be disposed. The plurality of sub pixels SP is the minimum units which configure the display area AA and a display element may be disposed in each of the plurality of sub pixels SP. The plurality of sub pixels SP may configure a pixel. For example, an organic light emitting diode which includes an anode, an organic emission layer, and a cathode may be disposed in each of the plurality of sub pixels SP, but it is not limited thereto. Further, a circuit for driving the plurality of sub pixels SP may include a driving element and a wiring line. For example, the circuit may be configured by a thin film transistor, a storage capacitor, a gate line, and a data line, but is not limited thereto.

The non-display area NA is an area where no image is displayed.

Even though in FIG. 1, it is illustrated that the non-display area NA encloses a quadrangular display area AA, shapes and placements of the display area AA and the non-display area NA are not limited to the example illustrated in FIG. 1.

The display area AA and the non-display area NA may have shapes suitable for a design of an electronic device including the display device. For example, the display area AA has various shapes, such as a pentagon, a hexagon, a circle, or an ellipse.

In the non-display area NA, various wiring lines and circuits for driving the organic light emitting diode of the display area AA may be disposed. For example, in the non-display area NA, a link line which transmits signals to the plurality of sub pixels SP and circuits of the display area AA or a driving IC, such as a gate driver IC or a data driver IC, may be disposed, but it is not limited thereto.

The display device 100 may include various additional elements to generate various signals or to drive the pixel in the display area AA. The additional elements for driving the pixels may include an inverter circuit, a multiplexer, or an electrostatic discharge (ESD) circuit. The display device 100 may further include an additional element associated with a function other than that of driving a pixel. For example, the display device 100 may include additional elements which provide a touch sensing function, a user authentication function (for example, fingerprint recognition), a multilevel pressure sensing function, or a tactile feedback function. The above-mentioned additional elements may be located in the non-display area NA and/or in an external circuit which is connected to the connecting interface.

The flexible film 180 is a film in which various components are disposed on a base film having a ductility. For example, the flexible film 180 is a film which supplies a signal to the plurality of sub pixels SP and the circuits of the display area AA and is electrically connected to the display panel. The flexible film 180 is disposed in one end of the non-display area NA of the display panel to supply a power voltage or a data voltage to the plurality of sub pixels SP and the circuits of the display area AA. The number of flexible films 180 may vary depending on the design, and is not limited thereto.

In the meantime, for example, a driving IC such as a gate driver IC or a data driver IC may be disposed on the flexible film 180. The driving IC is a component which processes data for displaying images and a driving signal for processing the data. The driving IC may be disposed by a chip on glass (COG), a chip on film (COF), or a tape carrier package (TCP) depending on a mounting method.

The printed circuit board 170 is disposed on one end of the flexible film 180 to be connected to the flexible film 180. The printed circuit board 170 is a component which supplies signals to the driving IC. The printed circuit board 170 may supply various signals such as a driving signal or a data signal to the driving IC. For example, a data driver which generates data signals may be mounted in the printed circuit board 170 and the generated data signal may be supplied to the plurality of sub pixels SP and the circuit of the display panel through the flexible film 180. The number of printed circuit boards 170 may vary depending on the design, and is not limited thereto.

In the meantime, according to the first exemplary embodiment of the present disclosure, a trench pattern 190 in which a planarization layer is partially removed is disposed in the non-display area NA and a cathode and an inorganic layer extend thereabove so as to cover the trench pattern 190. Therefore, according to the first exemplary embodiment of the present disclosure, a permeation speed of moisture and oxygen through a side surface of the display device is delayed.

The trench pattern 190 may be formed as a quadrangular frame shape along the non-display area NA of the display panel. That is, as illustrated in FIG. 1, the trench pattern 190 may be disposed on four edges of the display panel, but is not limited thereto. For example, in FIG. 1, it is not easy to form the trench pattern 190 on a lower side of the display panel due to the placement of the driving IC and the connection of the flexible film 180 so that the trench pattern 190 is not formed on the lower side of the display panel.

As described above, the encapsulation unit may include a sealing member and a reinforcement substrate 160.

According to the present disclosure, an encapsulation structure with a multilayered structure including a thicker reinforcement substrate 160 may be applied. In this case, the rigidity and the heat dissipation effect may be sufficiently ensured, but the present disclosure is not limited thereto.

In the meantime, according to the first exemplary embodiment of the present disclosure, the step relieving layer 140 is disposed between the cathode of the emission area and the inorganic layer to remove the step caused by the taper of the bank to minimize the permeation of moisture and oxygen to the light emitting diode.

The step relieving layer 140 of the first exemplary embodiment of the present disclosure may be disposed on the entire display area AA, but is not limited thereto. The step relieving layer 140 is disposed in a stripe shape on the sub pixels SP disposed in one direction or is disposed in a matrix in each sub pixel SP.

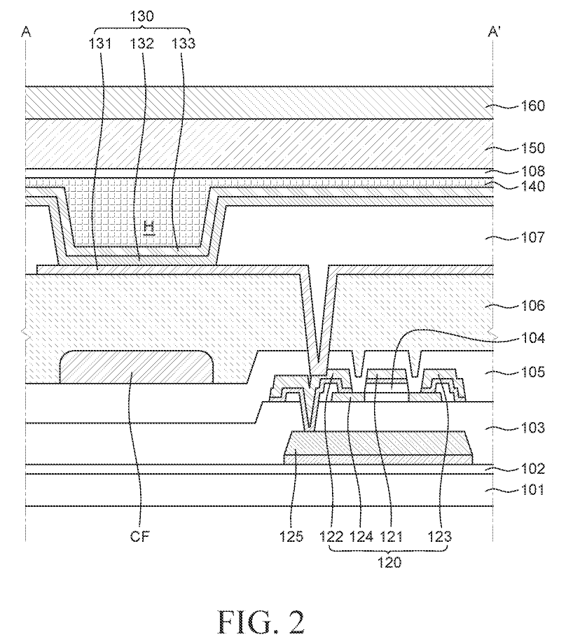

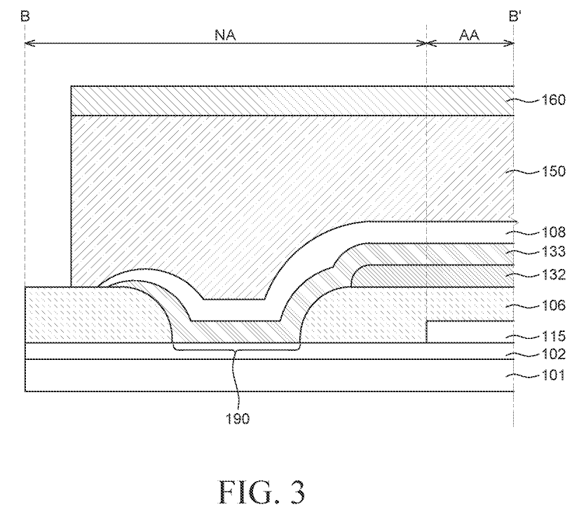

Hereinafter, the step relieving layer 140 and the trench pattern 190 according to the first exemplary embodiment will be described in detail with reference to FIGS. 2 and 3.

FIG. 2 is a cross-sectional view taken along the line A-A' of FIG. 1.

FIG. 3 is a cross-sectional view taken along the line B-B’ of FIG. 1.

FIG. 2 is a cross-sectional view for one sub pixel in a display device 100 of a first exemplary embodiment of the present disclosure and FIG. 3 illustrates a cross-section of an upper side of side portions of the display panel in which the trench pattern 190 is formed. In FIG. 3, for the convenience of description, the pixel unit 115 in the display area AA is schematically illustrated.

Referring to FIGS. 2 and 3, in the display panel according to the first exemplary embodiment of the present disclosure, a driving element 120 is disposed above the substrate 101.

A planarization layer 106 may be disposed above the driving element 120.

Further, a light emitting diode 130 which is electrically connected to the driving element 120 is disposed above the planarization layer 106 and a step relieving layer 140 and an inorganic layer 108 are disposed above the light emitting diode 130 to minimize permeation of oxygen and moisture to the light emitting diode 130.

The sealing member 150 and the reinforcement substrate 160 are sequentially disposed above the inorganic layer 108. However, the display panel according to the first exemplary embodiment of the present disclosure is not limited to this laminated structure.

The sealing member 150 is referred to as an adhesive layer and the reinforcement substrate 160 is referred to as an encapsulation substrate.

The substrate 101 may be a glass or plastic substrate.

When the substrate 101 is a plastic substrate, polyimide based or polycarbonate based materials are used so that the substrate may have a flexibility.

Polyimide may be applied to a high temperature process and is a coatable material so that polyimide may be frequently used for the plastic substrate.

A buffer layer 102 may be disposed on the substrate 101.

The buffer layer 102 is a functional layer which protects various electrodes and wiring lines from impurities such as alkali ions leaked from the substrate 101 or layers therebelow and has a multilayered structure which is formed by a first buffer layer and a second buffer layer, but is not limited thereto. For example, the buffer layer 102 may be formed of silicon oxide (SiOₓ), silicon nitride (SiNₓ), or multiple layers thereof.

The buffer layer 102 delays the diffusion of moisture and/or oxygen which permeates the substrate 101. Further, the buffer layer 102 may include a multi buffer layer and/or an active buffer layer.

For example, the buffer layer 102 extends to the end of the substrate 101 to the non-display area NA, but is not limited thereto.

A light shielding layer 125 may be disposed on the buffer layer 102. The light shielding layer 125 is formed to suppress external light from entering the active layer 124 of the driving element 120 disposed thereabove.

When the light shielding layer 125 is disposed on the buffer layer 102, the active buffer layer 103 is disposed on the light shielding layer 125. The active buffer layer 103 may perform functions of protecting an active layer 124 of the driving element 120 configured by a semiconductor and blocking various types of defects introduced from the substrate 101. For example, the active buffer layer 103 may be formed of amorphous silicon (a-Si).

The driving element 120 may be disposed above the active buffer layer 103.

For example, in the driving element 120, an active layer 124, a gate insulating layer 104, a gate electrode 121, a source electrode 123, and a drain electrode 122 are sequentially disposed and the driving element 120 is electrically connected to the light emitting diode 130 to transmit a current or a signal to the light emitting diode 130.

The active layer 124 may be disposed on the active buffer layer 103.

The active layer 124 may be made of polysilicon (p-Si). In this case, a predetermined region may also be doped with impurities. Further, the active layer 124 may be formed of amorphous silicon (a-Si) or various organic semiconductor materials such as pentacene. Moreover, the active layer 124 may be formed of oxide.

A gate insulating layer 104 may be disposed on the active layer 124.

The gate insulating layer 104 may be formed of an insulating inorganic material such as silicon oxide (SiOₓ) or silicon nitride (SiNₓ), and also, may be formed of an insulating organic material. The gate insulating layer 104 is disposed in an island shape on the active layer 124 below the gate electrode 121, the source electrode 123, and the drain electrode 122, but is not limited thereto and is disposed on the entire substrate 101.

The gate electrode 121, the source electrode 123, and the drain electrode 122 may be disposed on the gate insulating layer 104, but are not limited thereto and the gate electrode 121, the source electrode 123, and the drain electrode 122 may be disposed on different layers with an interlayer insulating layer interposed therebetween.

The gate electrode 121, the source electrode 123, and the drain electrode 122 may be formed of various conductive materials, for example, magnesium (Mg), aluminum (Al), nickel (Ni), chrome (Cr), molybdenum (Mo), tungsten (W), gold (Au), or an alloy thereof,

The gate insulating layer 104 is selectively removed to form a contact hole through which the source region and the drain region of the active layer 124 are exposed.

The source region and the drain region of the active layer 124 are electrically connected to the source electrode 123 and the drain electrode 122 through a contact hole.

A part of the drain electrode 122 is electrically connected to the light shielding layer 125 through another contact hole formed by removing the active buffer layer 103, but is not limited thereto.

A protection layer 105 which is configured by an inorganic insulating material may be disposed above the gate electrode 121, the source electrode 123, and the drain electrode 122 as needed to cover the gate electrode 121, the source electrode 123, and the drain electrode 122.

In the meantime, a color filter CF may be disposed on the protection layer 105, but is not limited thereto and the color filter CF may be omitted depending on the type of light emitting diode 130.

A color filter CF of each sub pixel may have any one color of red, green, and blue. Further, in a sub pixel in which white is implemented, the color filter CF may not be disposed. Red, green, and blue may be disposed in various forms.

In the case of the bottom emission type, the color filter CF may be located below the anode 131.

A planarization layer 106 may be disposed on the driving element 120 configured as described above.

The planarization layer 106 may have a multi-layered structure configured by at least two layers.

For example, the planarization layer 106 may extend to the end of the substrate 101 to the non-display area NA, but is not limited thereto and may be also disposed to be spaced apart from the end of the substrate 101 with a predetermined distance.

A thickness of the planarization layer 106 is approximately 2 μm, but is not limited thereto.

The planarization layer 106 may be an overcoat layer, but is not limited thereto.

The planarization layer 106 is configured by two layers because as the resolution of the display panel is increased, various signal lines are increased. Therefore, it is difficult to place all the wiring lines on one layer while ensuring a minimum interval so that an additional layer is provided. There is a margin in the placement of the wiring line by adding the additional layer, which makes it easier to design the electric wire/electrode placement. Further, when a dielectric material is used for the planarization layer 106 configured by a plurality of layers, the planarization layer 106 may be utilized to form a capacitance between metal layers.

The planarization layer 106 and the protection layer 105 may be formed to expose a part of the drain electrode 122 and the drain electrode 122 of the driving element 120 and the anode 131 of the light emitting diode 130 may be electrically connected through another contact hole.

The light emitting diode 130 is disposed above the planarization layer 106. The light emitting diode 130 may be configured by sequentially disposing the anode 131, the plurality of organic layers 132, and the cathode 133. The light emitting diode 130 may be configured by the anode 131 disposed on the planarization layer 106, the organic layer 132 disposed on the anode 131, and the cathode 133 disposed on the organic layer 132.

The display device may be implemented as a top emission type or a bottom emission type. In the case of the top emission type, a reflective layer may be additionally formed below the anode 131 to allow light emitted from the organic layer 132 to be reflected by the anode 131 to be directed upwardly, for example, directed to the cathode 133 thereabove. The reflective layer may be formed of an opaque conductive material having a high reflectance, such as silver (Ag), aluminum (Al), gold (Au), molybdenum (Mo), tungsten (W), chrome (Cr), or an alloy thereof. In contrast, in the case of the bottom emission type, the anode 131 may be only formed of a transparent conductive material, such as indium tin oxide (ITO), indium zinc oxide (IZO), or indium gallium zinc oxide (IGZO). Hereinafter, it is assumed that the display panel of the present disclosure is a bottom emission type.

The bank 107 may be disposed in a remaining area excluding the emission area on the planarization layer 106. That is, the bank 107 may have a bank hole H which exposes the anode 131 corresponding to the emission area. For example, the bank 107 may be formed of an inorganic insulating material, such as silicon nitride (SiNₓ) or silicon oxide (SiOₓ), or an organic insulating material, such as BCB, an acrylic resin or an imide resin.

A thickness of the bank 107 is approximately 1 μm, but is not limited thereto.

The organic layer 132 may be disposed on the anode 131 exposed by the bank 107. The organic layer 132 may include an emission layer, an electron injection layer, an electron transport layer, a hole transport layer, and a hole injection layer.

For example, the organic layer 132 may be disposed above the bank 107 including a bank hole H of the bank 107, but is not limited thereto and a partial organic layer 132 may be also disposed only on the anode 131.

The organic layer 132 may extend to the non-display area NA.

The cathode 133 may be disposed on the organic layer 132.

In the case of the top emission type, the cathode 133 may include a transparent conductive material. For example, the cathode 133 may be formed of indium tin oxide (ITO), indium zinc oxide (IZO), or indium gallium zinc oxide (IGZO). In the case of the bottom emission type, the cathode 133 may include any one of a group consisting of metal materials such as gold (Au), silver (Ag), aluminum (Al), molybdenum (Mo), magnesium (Mg), palladium (Pd), copper (CU), and an alloy thereof. Alternatively, the cathode 133 may be configured by laminating a layer formed of a transparent conductive layer such as indium tin oxide (ITO), indium zinc oxide (IZO), or indium gallium zinc oxide (IGZO) and a layer formed of a metal material such as gold (Au), silver (Ag), aluminum (Al), molybdenum (Mo), magnesium (Mg), palladium (Pd), copper (CU), or an alloy thereof, but is not limited thereto.

The cathode 133 may extend to the non-display area NA.

The cathode 133 is spaced apart from an end of the planarization layer 106 with a predetermined distance in the non-display area NA to be in contact with a part of a top surface of the planarization layer 106, but is not limited thereto.

The cathode 133 may be disposed to cover the side surface of the organic layer 132 in the non-display area NA. The organic layer 132 may be disposed to be spaced apart from an end of the cathode 133 with a predetermined distance, but is not limited thereto.

The inorganic layer 108 may be disposed on the light emitting diode 130.

The inorganic layer 108 may extend to the non-display area NA.

The inorganic layer 108 may be disposed to be spaced apart from the end of the planarization layer 106 with a predetermined distance in the non-display area NA to cover a side surface of the cathode 133. The cathode 133 may be disposed to be spaced apart from the end of the inorganic layer 108 with a predetermined distance, but the present disclosure is not limited thereto.

The capping layer (not illustrated) which is formed of a material having a high refractive index and a high light absorptance may be disposed between the light emitting diode 130 and the inorganic layer 108 to reduce irregular reflection of external light.

In the meantime, according to the first exemplary embodiment of the present disclosure, a partial area of the planarization layer 106 is removed to form the trench pattern 190 in the non-display area NA. For example, the trench pattern 190 may be disposed in the non-display area NA at the outer periphery of the display area AA.

In the plan view, the trench pattern 190 may be formed as a quadrangular frame shape along the non-display area NA of the display panel. For example, the trench pattern 190 may be disposed on four edges of the display panel, but the present disclosure is not limited thereto and the trench pattern 190 may not be formed on a lower side of the display panel to which the flexible film is connected.

The trench pattern 190 may be formed by removing the planarization layer 106 of the non-display area NA at the outer periphery of the display area AA through a photo process, for example, but the present disclosure is not limited thereto.

Even though in FIG. 3, it is illustrated that one trench pattern 190 is provided, it is not limited thereto. That is, two or more trench patterns 190 may be provided and it is not limited to the number of trench patterns 190 illustrated in FIG. 3.

The trench pattern 190 may function to delay or partially block permeation of moisture and oxygen which enters from the outside through the planarization layer 106 which is an organic film.

As described above, the cathode 133 configured by a metal material and the inorganic layer 108 configured by an inorganic insulating material are deposited in the trench pattern 190 to minimize the permeation of moisture and oxygen.

In the meantime, according to the first exemplary embodiment of the present disclosure, the step relieving layer 140 is disposed in the display area AA before depositing the inorganic layer 108.

For example, the step relieving layer 140 (FIGS. 1 and 2) includes a bank hole H to be disposed on the cathode 133 on the entire surface of the display area AA.

In the meantime, the dummy pixel may be disposed on the edge of the display area AA and in this case, there is no need to apply the step relieving layer 140 in the dummy pixel, but is not limited thereto.

As described above, the step relieving layer 140 is disposed to be filled in the bank hole H so that the step due to the bank hole H is relieved and the upper portion of the bank hole H is planarized. Therefore, the cracking of the cathode 133 and the inorganic layer 108 in the bank hole H due to the bubbles generated during the bonding process of the encapsulation unit may be effectively suppressed.

Specifically, bubbles of several tens of μm to several μm may be generated during the bonding process of the encapsulation unit. At this time, due to the taper of the bank 107, the cathode 133 and the inorganic layer 108 in the bank hole H have poorer film quality compared to the cathode 133 and the inorganic layer 108 in the other area and a fine crack may be generated due to the step. The moisture and oxygen in the bubbles permeate through the fine cracks of the cathode 133 and the inorganic layer 108, which causes a negative shift of the driving element 120 or damage to the light emitting diode 130.

Accordingly, according to the first exemplary embodiment of the present disclosure, the step relieving layer 140 is disposed between the cathode 133 and the inorganic layer 108 so as to be filled in the bank hole H to remove the step caused by the taper of the bank 107, thereby minimizing the permeation of moisture and oxygen to the light emitting diode 130. Therefore, the lifespan and reliability of the display device may be improved.

Further, the step relieving layer 140 may be formed of an organic material. For example, the step relieving layer 140 may include resin formed of an organic material and getters dispersed in the resin, but is not limited thereto and may not include the getters.

Further, for example, the step relieving layer 140 may be formed of a thermosetting resin or an UV curable resin.

The resin of the step relieving layer 140 may be formed of an organic material. For example, the step relieving layer 140 may include epoxy resin, acrylic resin, and silicon oxy carbon (SiOC) resin.

The step relieving layer 140 may include getters. The getters may be dispersed in the above-mentioned resin. The getter may include at least any one of barium oxide (BaO), calcium oxide (CaO), magnesium oxide (MgO), magnesium sulfate (MgSO₄), sodium oxide (Na₂O), sodium sulfate (Na₂SO₄), lithium sulfate (LiSO), calcium sulfate (CaSO₄), potassium oxide (K₂O), lithium oxide (Li₂O), gallium sulfate (Ga₂(SO₄)₃), calcium chloride (CaCl₂), magnesium chloride (MgCl₂), calcium bromide (CaBr₂), cerium bromide (CeBr₃), vanadium bromide (VBr₅), and calcium nitrate (Ca(NO₃)₂). The getter may be configured by a transparent material, but is not limited thereto.

For example, the step relieving layer 140 may be implemented in the form of film.

The inorganic layer 108 which is formed of an inorganic insulating material may be disposed on the step relieving layer 140. The inorganic layer 108 delays the moisture permeation in the upper portion, and suppresses the defect caused by dent or foreign materials.

The inorganic layer 108 may be disposed to be in contact with the top surface of the step relieving layer 140. Further, the inorganic layer 108 covers a top surface and a side surface of the step relieving layer 140 to seal the step relieving layer 140, but is not limited thereto.

In order to delay the moisture permeation, the inorganic layer 108 may be configured by silicon oxide (SiOₓ), silicon nitride (SiNₓ), or multi-layers thereof, but is not limited thereto.

The sealing member 150 and the reinforcement substrate 160 may be disposed above the inorganic layer 108.

The sealing member 150 and the reinforcement substrate 160 may extend to the non-display area NA so as to cover a part of the planarization layer 106 and the inorganic layer 108.

The sealing member 150 may be disposed so as to enclose the inorganic layer 108, the cathode 133, and the pixel unit 115, including the trench pattern 190. The sealing member 150 may protect the light emitting diode 130 of the pixel unit 115 from moisture, oxygen, and impacts of the outside together with the inorganic layer 108 and the reinforcement substrate 160.

The sealing member 150 may further include an absorbent. The absorbent may be particles having hygroscopicity and absorb moisture and oxygen to minimize permeation of the moisture and oxygen into the pixel unit 115.

The reinforcement substrate 160 may be disposed on the sealing member 150. The reinforcement substrate 160 may protect the light emitting diode 130 of the pixel unit 115 together with the sealing member 150. The reinforcement substrate 160 may protect the light emitting diode 130 from moisture, oxygen, and impacts of the outside.

For example, the reinforcement substrate 160 may be configured by Invar which is an iron/nickel alloy, but is not limited thereto. As the encapsulation structure of the present disclosure, a multi-layered structure including a barrier layer such as a thin-film metal layer or aluminum foil (Al foil) and a reinforcement substrate such as a plurality of adhesive layers and an aluminum sheet may be applied.

That is, the encapsulation structure with a multilayered structure configured by the sealing member 150 and the reinforcement substrate 160 may be disposed above the inorganic layer 108. The reinforcement substrate 160 may also be omitted.

In a small sized display panel used for mobile or portable devices, a display panel has a small area so that heat is quickly released from the device and there are few problems in adhesion. However, in a large sized display panel used for monitors, tablets, or television receivers, the display panel has a large area so that an encapsulation structure for optimal heat dissipation effect and adhesion is necessary.

Further, in order to ensure the sufficient rigidity, the display device may further include a separate inner plate above the encapsulation substrate. In this case, there are problems in that it is necessary to ensure a space for placing the separate inner plate and it is limited in slimming and lightening the display device due to the weight of the inner plate. Further, a vertical space is caused by an air gap generated between the encapsulation substrate and the inner plate as much as a thickness of the adhesive tape disposed to bond the encapsulation substrate and the inner plate, which degrades the heat dissipation performance.

Therefore, according to the present disclosure, an encapsulation structure with a multilayered structure including the sealing member 150 which fixes a relatively thick reinforcement substrate 160 while removing the separate inner plate and suppresses the process failure may be applied.

For example, the sealing member 150 of the present disclosure may include a first adhesive layer which is opposite to the substrate 101, a second adhesive layer which is opposite to the reinforcement substrate 160, and a barrier layer between the first adhesive layer and the second adhesive layer, but is not limited thereto.

The first adhesive layer and the second adhesive layer may be formed of a polymer material having adhesiveness. For example, the first adhesive layer may be formed of any one of olefin-based, epoxy-based, and acrylate-based polymer materials. The second adhesive layer may be formed of any one of olefin-based, epoxy-based, acrylate-based, amine-based, phenol-based, and acid anhydride-based polymer materials which do not contain a carboxyl group. Specifically, the second adhesive layer is desirably configured by a polymer material which does not include a carboxyl group, for film uniformity and anti-corrosion of the barrier layer.

in order to dissipate the heat of the substrate 101, at least the first adhesive layer, between the first and second adhesive layers, may be formed of a mixture including an adhesive polymer material and particles of a metal material. For example, the particles of the metal material may be powders formed of nickel (Ni). That is, the first adhesive layer which is in direct contact with the substrate 101 is configured of a mixture including an adhesive polymer material and particles of a metal material so that a thermal conductivity thereof may be higher than that of the adhesive polymer material.

Similarly, the second adhesive layer is also formed of a mixture including an adhesive polymer material and particles of a metal material so that a thermal conductivity thereof may be higher than that of the adhesive polymer material.

By doing this, a speed of releasing a driving heat generated in the substrate 101 through the sealing member 150 is improved so that a heat dissipation effect of the substrate 101 may be improved.

Further, in order to suppress the moisture permeation to the pixel unit 115, the first adhesive layer may be formed of a mixture further including a hygroscopic inorganic filler. For example, the hygroscopic inorganic filler may be at least one of barium oxide (BaO), calcium oxide (CaO), and magnesium oxide (MgO).

Unlike the first adhesive layer, the second adhesive layer is not in direct contact with the pixel unit 115 so that it is not necessary to include an inorganic filler for suppressing the moisture permeation of the pixel unit 115. Therefore, the second adhesive layer does not include the hygroscopic inorganic filler, but includes only the adhesive polymer material and particles of the metal material. By doing this, an amount of expensive hydroscopic inorganic filler which is injected into the sealing member 150 is reduced so that a preparing cost for the sealing member 150 is reduced.

Further, since the hydroscopic inorganic filler is not included, a mixing ratio of the polymer material included in the second adhesive layer is increased as compared with the first adhesive layer. Accordingly, the adhesiveness of the second adhesive layer may be improved more than the adhesiveness of the first adhesive layer. Accordingly, as the reinforcement substrate 160 is more firmly fixed onto the second adhesive layer, the reliability for the adhesiveness between the substrate 101 and the reinforcement substrate 160 may be further improved.

Further, as the first adhesive layer and the second adhesive layer are formed with a multilayered structure, a reliability of reducing a warpage phenomenon that the display panel is bent may be also improved.

A thickness of each of the first and second adhesive layers may be limited to a threshold thickness or lower which suppresses the process failure. Further, a sum of thicknesses of the first and second adhesive layers may be limited to a threshold thicknesses or higher to ensure the reliability for fixing the reinforcement substrate 160.

For example, thicknesses of the first and second adhesive layers may be within a range of 10 um to 100 um.

The barrier layer may be formed of a metal material. That is, the barrier layer may be formed to include a metal material, such as Al, Cu, Sn, Ag, Fe, or Zn.

The barrier layer may be introduced to be implemented as a laminated structure to reinforce bonding with the first and second adhesive layers and reduce the warpage.

Specifically, the first and second adhesive layers are configured to include an adhesive polymer material. Therefore, the barrier layer which has a harder material is disposed between the first adhesive layer and the second adhesive layer to be bonded to one surface and the other surface of the barrier layer, thereby improving the adhesiveness.

At this time, the thickness of the barrier layer may be limited to a value smaller than the thickness of the first and second adhesive layers to minimize the increase in the thickness of the sealing member 150 due to the barrier layer. For example, the thickness of the barrier layer may be within a range which is larger than 10 um and smaller than the thicknesses of the first and second adhesive layers.

The sealing member 150 according to the first exemplary embodiment of the present disclosure includes the first and second adhesive layers which are separated by the barrier layer so that it is implemented to have a thickness approximately two times thicker than the adhesive material of a single layer, without causing a process failure. Accordingly, the reinforcement substrate 160 which is fixed by the sealing member 150 is prepared to have a larger thickness so that it is advantageous to easily increase the rigidity and improve a heat dissipation effect. For example, when the thickness of the sealing member 150 is within a range of 30 um to 300 um, the thickness of the reinforcement substrate 160 may be implemented to be a thickness in the range of 0.1 mm to 1.5 mm.

For example, the reinforcement substrate 160 may be formed of any one material of glass and plastic polymer such as PET.

For example, the sealing member 150 and the reinforcement substrate 160 may extend to the non-display area NA so as to cover a part of the planarization layer 106 and the inorganic layer 108.

In the meantime, according to the present disclosure, the step relieving layer of the display area is disposed in a matrix in each sub pixel to minimize the process, which will be described in detail with reference to the drawings.

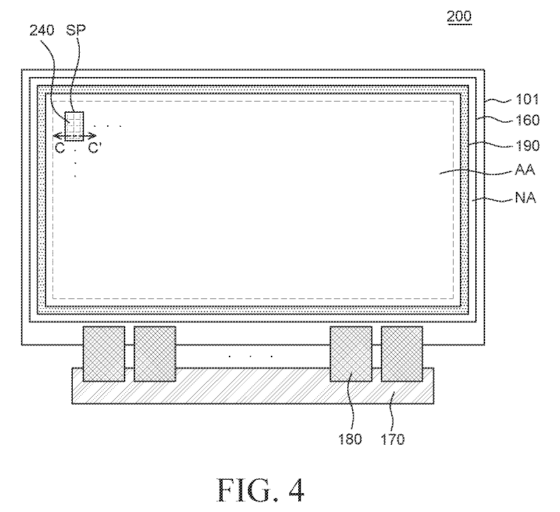

FIG. 4 is a plan view schematically illustrating a display device according to a second exemplary embodiment of the present disclosure.

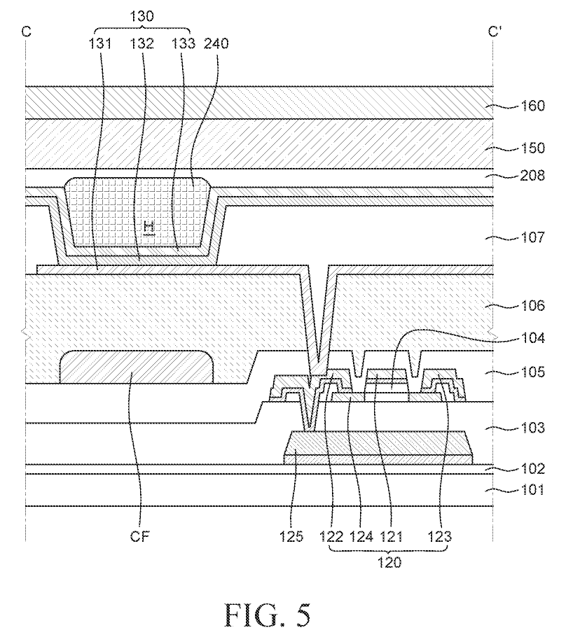

FIG. 5 is a cross-sectional view taken along the line C-C' of FIG. 4.

A second exemplary embodiment of the present disclosure of FIGS. 4 and 5 has the substantially same configuration as the first exemplary embodiment of FIGS. 1 to 3 except for a step relieving layer 240, so that a redundant description will be omitted. The same configuration will be denoted by the same reference numeral. Hereinafter, the description for the same reference numeral may refer to FIGS. 1 to 3.

FIG. 5 is a cross-sectional view of one sub pixel SP of a display device 200 according to a second exemplary embodiment of the present disclosure.

Referring to FIGS. 4 and 5, in the display panel according to the second exemplary embodiment of the present disclosure, a driving element 120 may be disposed above the substrate 101.

A planarization layer 106 may be disposed above the driving element 120.

Further, a light emitting diode 130 which is electrically connected to the driving element 120 is disposed above the planarization layer 106 and a step relieving layer 240 and an inorganic layer 208 are disposed above the light emitting diode 130 to suppress oxygen and moisture from permeating into the light emitting diode 130.

A sealing member 150 and a reinforcement substrate 160 may be sequentially disposed above the inorganic layer 208. However, the display panel according to the second exemplary embodiment of the present disclosure is not limited to this laminated structure.

The light emitting diode 130 may be disposed above the planarization layer 106. The light emitting diode 130 may be configured by the anode 131 disposed on the planarization layer 106, the organic layer 132 disposed on the anode 131, and the cathode 133 disposed on the organic layer 132.

The bank 107 may be disposed in a remaining area excluding the emission area on the planarization layer 106. That is, the bank 107 may have a bank hole H which exposes the anode 131 corresponding to the emission area.

The organic layer 132 may be disposed on the anode 131 exposed by the bank 107. The organic layer 132 may include an emission layer, an electron injection layer, an electron transport layer, a hole transport layer, and a hole injection layer.

For example, the organic layer 132 may be disposed above the bank 107, including a bank hole H of the bank 107, but is not limited thereto and a partial organic layer 132 may be disposed only on the anode 131.

The cathode 133 may be disposed on the organic layer 132.

The step relieving layer 240 may be disposed above the light emitting diode 130.

The step relieving layer 240 of the second exemplary embodiment of the present disclosure is disposed only in the bank hole H. For example, the step relieving layer 240 is disposed in a matrix in each sub pixel SP so that a process and the cost may be minimized.

For example, the step relieving layer 240 may be formed to partially protrude from the top of the cathode 133 while being filled in the bank hole H, but is not limited thereto. At this time, for example, the step relieving layer 240 may cover a part of the cathode 133 above the bank 107.

For example, the step relieving layer 240 may also have an upward convex shape.

For example, in the plan view, the step relieving layer 240 may have the substantially same shape as the shape of the sub pixel SP. In the plan view, the step relieving layer 240 may have the substantially same shape as the shape of the bank hole H.

As described above, the step relieving layer 240 is disposed so as to be filled in the bank hole H so that the step due to the taper of the bank 107 may be removed. Therefore, the crack of the cathode 133 and the inorganic layer 108 in the bank hole H due to the bubbles generated during the bonding process of the encapsulation unit is suppressed to minimize the permeation of moisture and oxygen to the light emitting diode 130.

Further, the step relieving layer 240 may be formed of an organic material. For example, the step relieving layer 240 may include resin formed of an organic material and getters dispersed in the resin, but is not limited thereto and may not include the getters.

Further, for example, the step relieving layer 240 may be formed of a thermosetting resin or an UV curable resin.

The inorganic layer 208 which is formed of an inorganic insulating material may be disposed on the step relieving layer 240.

According to the second exemplary embodiment of the present disclosure, the inorganic layer 208 may be disposed so as to be in contact with the top surface of the step reliving layer 240 and the cathode 133 above the bank 107. The inorganic layer 208 may cover the cathode 133 above the bank 107 including the step relieving layer 240.

The sealing member 150 and the reinforcement substrate 160 may be disposed above the inorganic layer 208.

In the meantime, according to the present disclosure, a plurality of concave portions is formed on a surface of the planarization layer corresponding to the bank hole to improve the light extraction efficiency, which will be described with reference to the drawing.

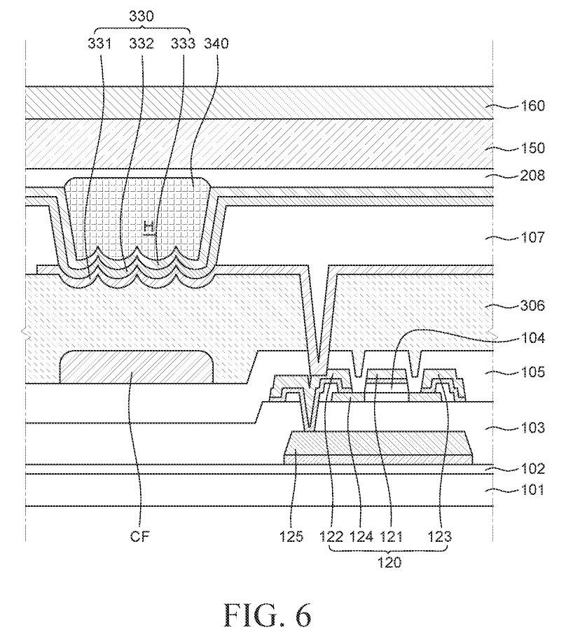

FIG. 6 is a cross-sectional view schematically illustrating a display device according to a third exemplary embodiment of the present disclosure.

A third exemplary embodiment of the present disclosure of FIG. 6 has the substantially same configuration as the second exemplary embodiment of FIGS. 4 and 5 except for a planarization layer 306 and a configuration of a light emitting diode 330 and a step relieving layer 340 so that a redundant description will be omitted. The same configuration will be denoted by the same reference numeral. Hereinafter, the description for the same reference numeral may refer to FIGS. 1 to 5.

FIG. 6 is a cross-sectional view of one sub pixel of a display device according to a third exemplary embodiment of the present disclosure.

Referring to FIG. 6, in the display panel according to the third exemplary embodiment of the present disclosure, a driving element 120 may be disposed above the substrate 101.

A planarization layer 306 may be disposed above the driving element 120.

Further, a light emitting diode 330 which is electrically connected to the driving element 120 may be disposed above the planarization layer 306 and a step relieving layer 340 and an inorganic layer 208 may be disposed above the light emitting diode 330.

A sealing member 150 and a reinforcement substrate 160 may be sequentially disposed above the inorganic layer 208. However, the display panel according to the third exemplary embodiment of the present disclosure is not limited to this laminated structure.

The planarization layer 306 according to the third exemplary embodiment of the present disclosure includes a plurality of concave portions formed on a top surface so as to overlap with the color filter CF.

The plurality of concave portions may have a hemispherical shape or a semi-ellipsoidal shape, but is not limited thereto.

The light emitting diode 330 may be disposed above the planarization layer 306 having the plurality of concave portions. The light emitting diode 330 may be configured by the anode 331 disposed on the planarization layer 306, the organic layer 332 disposed on the anode 331, and the cathode 333 disposed on the organic layer 332.

A top surface of the light emitting diodes 330, that is, top surfaces of the anode 331, the organic layer 332, and the cathode 333 may have a plurality of concave portions according to the shape of the concave portion of the planarization layer 306.

Specifically, light emitted from an emission layer of a bottom-emission type display device is largely divided into an ITO/organic film mode (hereinafter, referred to as an “ITO” mode), a substrate mode, and an air mode based on a light propagation path. The air mode refers to light which is extracted to the outside of the display device, among light emitted from the emission layer and the substrate mode refers to light which is trapped in the display device by the total reflection and light absorption in the substrate, among light emitted from the emission layer. The ITO mode refers to light which is trapped in the display device by the total reflection and light absorption in an anode which is generally formed by ITO, among light emitted from the emission layer. At this time, in the bottom emission type display device, light which is trapped in the display device as the ITO mode is approximately 50% of light emitted from the emission layer and light which is trapped in the display device as the substrate mode is approximately 30% of light emitted from the emission layer. Accordingly, only approximately 80% of light, among light emitted from the emission layer, is trapped in the display device and only approximately 20% of light is extracted to the outside, so that it is very important to improve the light extraction efficiency of the display device.

The concave portions of the planarization layer 306 and the light emitting diode 330 may form a micro lens array (MLA) structure. Accordingly, an incident angle of light emitted from the emission layer, which is incident on the interface of the planarization layer 306, is highly likely to be smaller than a critical angle of total internal reflection to reduce an amount of light trapped in the display device as the ITO mode. Further, light emitted from the emission layer passes through the interface of the planarization layer 306 and travels at an angle which is almost perpendicular to the bottom surface of the substrate 101. Accordingly, an incident angle of light which passes through the interface of the planarization layer 306 is highly likely to be smaller than a critical angle of total internal reflection for the substrate mode to reduce an amount of light trapped in the display device as the substrate mode. Further, multiple reflections of light emitted from the interface of the planarization layer 306 are enabled to increase the number of times that the light is recycled and encounters the MLA structure of the planarization layer 306 and the light-emitting diode 330. As described above, an amount of light which is trapped in the display device as the ITO mode and the substrate mode is reduced to increase the light extraction efficiency and the lifespan of the light emitting diode 330, thereby improving power efficiency. Accordingly, it is possible to implement ESG (Environment/Social/Governance) by reducing greenhouse gas emissions through reducing the use of fossil fuels for power generation.

In the meantime, when the MLA structure is formed in the light emitting diode 330, a thickness of the cathode 333 and the inorganic layer 208 which are deposited above the taper (approximately 30 to 40 degrees) of the bank 107 is likely to be reduced. In this case, the possibility of cracks occurring in the cathode 333 and the inorganic layer 208 due to bubbles generated during bonding of the encapsulation unit may further increase. Accordingly, oxygen in the bubbles may cause the deterioration of the light emitting diode 330.

Therefore, according to the third exemplary embodiment of the present disclosure, the step relieving layer 340 is applied above the light emitting diode 330 having a concave portion to remove the step. Accordingly, the crack of the cathode 333 and the inorganic layer 208 due to the bubbles is suppressed to minimize permeation of the moisture and oxygen to the light emitting diode 330.

The step relieving layer 340 of the third exemplary embodiment of the present disclosure is disposed only in the bank hole H. That is, for example, the step relieving layer 340 is disposed in a matrix in each sub pixel so that the process and the cost may be minimized.

The step relieving layer 340 may be formed to partially protrude from the top of the cathode 333 while being filled in the bank hole H in which the light emitting diode 330 has a concave portion, but is not limited thereto.

For example, the step relieving layer 340 may have an upward convex shape.

Further, the step relieving layer 340 may be formed of an organic material. For example, the step relieving layer 340 may include resin formed of an organic material and getters dispersed in the resin, but is not limited thereto and may not include the getters.

Further, for example, the step relieving layer 340 may be formed of a thermosetting resin or an UV curable resin.

The inorganic layer 208 which is formed of an inorganic insulating material may be disposed on the step relieving layer 340.

The sealing member 150 and the reinforcement substrate 160 may be disposed above the inorganic layer 208.

In the meantime, according to the present disclosure, the step relieving layer is additionally disposed also on a side surface of the trench pattern so that permeation of moisture and oxygen to the display device may be more effectively blocked, which will be described with reference to the drawings.

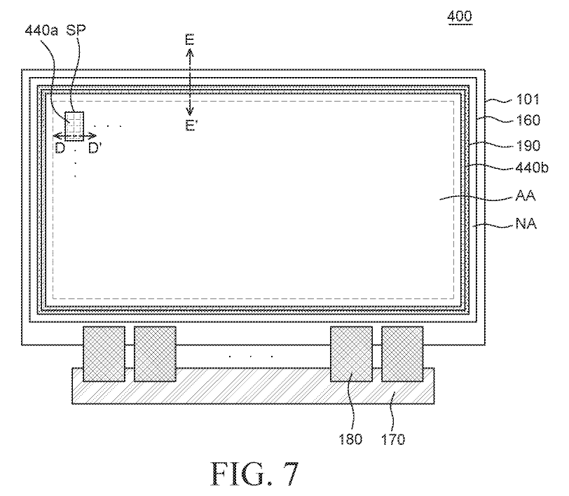

FIG. 7 is a plan view schematically illustrating a display device according to a fourth exemplary embodiment of the present disclosure.

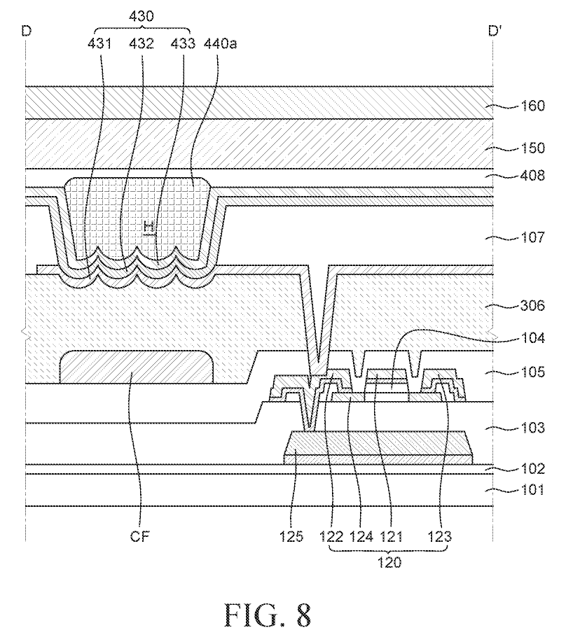

FIG. 8 is a cross-sectional view taken along the line D-D' of FIG. 7.

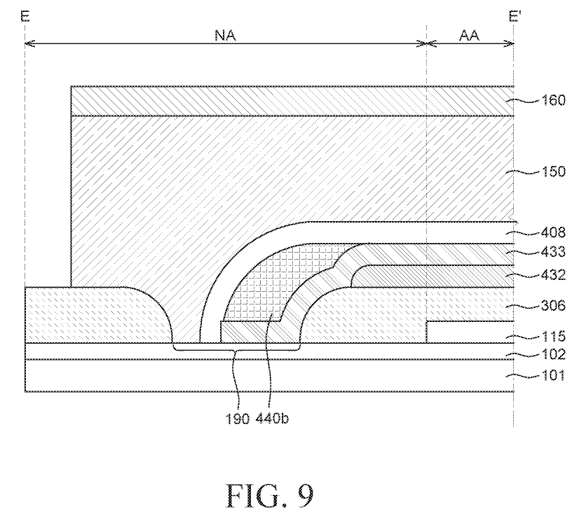

FIG. 9 is a cross-sectional view taken along the line E-E' of FIG. 7.

A fourth exemplary embodiment of the present disclosure of FIGS. 7 to 9 has the substantially same configuration as the second exemplary embodiment of FIGS. 4 and 5 and the third exemplary embodiment of FIG. 6 except that a second step relieving layer 440b is additionally disposed on a side surface of the trench pattern 190 so that a redundant description will be omitted. The same configuration will be denoted by the same reference numeral. Hereinafter, the description for the same reference numeral may refer to FIGS. 1 to 6.

FIG. 8 is a cross-sectional view of one sub pixel SP of a display device 400 according to a fourth exemplary embodiment of the present disclosure.

FIG. 9 is a cross-sectional view of a non-display area NA in the display device 400 of the fourth exemplary embodiment of the present disclosure and illustrates a cross-section of an upper side, among side portions of the display panel in which the trench pattern 190 is formed. In FIG. 9, for the convenience of description, the pixel unit 115 in the display area AA is schematically illustrated.

Referring to FIGS. 7 to 9, in the display panel according to the fourth exemplary embodiment of the present disclosure, a driving element 120 may be disposed above the substrate 101.

A planarization layer 306 may be disposed above the driving element 120.

A light emitting diode 430 which is electrically connected to the driving element 120 may be disposed above the planarization layer 306. Further, a first step relieving layer 440a and an inorganic layer 408 may be disposed above the light emitting diode 430.

A sealing member 150 and a reinforcement substrate 160 may be sequentially disposed above the inorganic layer 408. However, the display panel according to the fourth exemplary embodiment of the present disclosure is not limited to this laminated structure.

The planarization layer 306 of the fourth exemplary embodiment of the present disclosure may include a plurality of concave portions formed on the top surface so as to overlap with the color filter CF, similar to the above-described third exemplary embodiment.

The plurality of concave portions may have a hemispherical shape or a semi-ellipsoidal shape, but is not limited thereto.

Further, the planarization layer 306 may extend to the end of the substrate 101 to the non-display area NA, but is not limited thereto and may be also disposed to be spaced apart from the end of the substrate 101 with a predetermined distance.

The light emitting diode 430 may be disposed above the planarization layer 306 having the plurality of concave portions. Top surfaces of an anode 431, an organic layer 432, and a cathode 433 may have a plurality of concave portions according to the shape of the concave portion of the planarization layer 306.

The organic layer 432 may extend to the non-display area NA.

The cathode 433 may extend to the non-display area NA.

The cathode 433 is spaced apart from an end of the planarization layer 306 with a predetermined distance in the non-display area NA to be in contact with a part of a side surface of the planarization layer 306 in the trench pattern 190, but is not limited thereto.

The cathode 433 may be disposed so as to cover the side surface of the organic layer 432 in the non-display area NA. The organic layer 432 may be disposed to be spaced apart from an end of the cathode 433 with a predetermined distance, but is not limited thereto.

The cathode 433 according to the fourth exemplary embodiment of the present disclosure may be disposed so as to expose a part of the trench pattern 190 and cover the other part, but is not limited thereto.

A first step relieving layer 440a may be disposed above the light emitting diode 430.

Therefore, according to the fourth exemplary embodiment of the present disclosure, the first step relieving layer 440a is applied above the light emitting diode 430 having a concave portion to remove the step.

The first step relieving layer 440a of the fourth exemplary embodiment of the present disclosure is disposed only in the bank hole H. For example, the first step relieving layer 440a may be disposed in a matrix in each sub pixel SP.

The first step relieving layer 440a may be formed to partially protrude from the top of the cathode 433 while being filled in the bank hole H in which the light emitting diode 430 has a concave portion, but is not limited thereto.

For example, the first step relieving layer 440a may have an upward convex shape.

In the meantime, according to the fourth exemplary embodiment of the present disclosure, a second step relieving layer 440b is disposed on a side surface of the trench pattern 190.

For example, the second step relieving layer 440b may be disposed only on the side surface of the trench pattern 190 therein, but is not limited thereto, and may be also disposed on the side surface of the trench pattern 190 therein or outside.

For example, the second step relieving layer 440b may be disposed so as to cover an end portion of the cathode 433 in the trench pattern 190.

As described above, according to the fourth exemplary embodiment of the present disclosure, the second step relieving layer 440b is formed so as to cover the cathode 433 in the trench pattern 190 having a step so that the permeation of moisture and oxygen into the display device 400 may be more effectively blocked. Accordingly, the lifespan and the reliability of the display device 400 may be further improved.

The first step relieving layer 440a and the second step relieving layer 440b may be formed of an organic material. For example, the first step relieving layer 440a and the second step relieving layer 440b may include resin formed of an organic material and getters dispersed in the resin, but is not limited thereto and may not include the getters.

Further, for example, the first step relieving layer 440a and the second step relieving layer 440b may be formed of a thermosetting resin or a UV curable resin.

An inorganic layer 408 may be disposed on the first step relieving layer 440a and the second step relieving layer 440b.

The inorganic layer 408 may extend to the non-display area NA.

The inorganic layer 408 may be disposed to be spaced apart from the end of the planarization layer 306 with a predetermined distance in the non-display area NA to cover a side surface of the cathode 433 in the trench pattern 190. The cathode 433 may be disposed to be spaced apart from the end of the inorganic layer 408 with a predetermined distance, but the present disclosure is not limited thereto.

The inorganic layer 408 may be disposed to be in contact with a top surface and a side surface of the second step relieving layer 440b. Further, the inorganic layer 408 may cover a top surface and a side surface of the second step relieving layer 440b to seal the second step relieving layer 440b, but is not limited thereto.

In the meantime, the second step relieving layer of the present disclosure may be formed to be filled in the trench pattern, which will be described in detail with reference to the drawing.

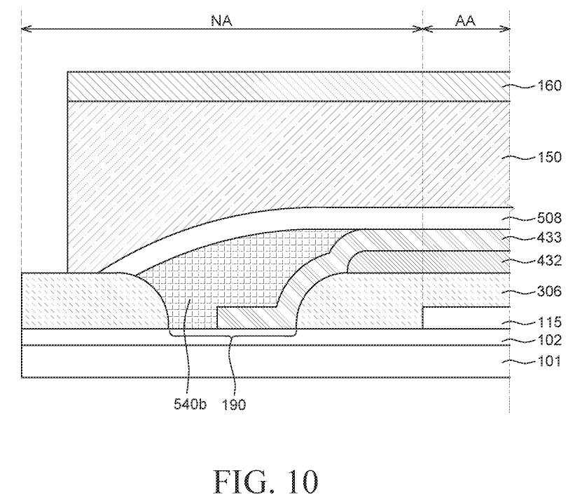

FIG. 10 is a cross-sectional view schematically illustrating a display device according to a fifth exemplary embodiment of the present disclosure.

A fifth exemplary embodiment of the present disclosure of FIG. 10 has the substantially same configuration as the fourth exemplary embodiment of FIGS. 7 to 9 except for a configuration of a second step relieving layer 540b so that a redundant description will be omitted. The same configuration will be denoted by the same reference numeral. Hereinafter, the description for the same reference numeral may refer to FIGS. 1 to 9.

FIG. 10 is a cross-sectional view of a non-display area NA in a display device of the fifth exemplary embodiment of the present disclosure and illustrates a cross-section of an upper side, among side portions of the display panel in which the trench pattern 190 is formed. In FIG. 10, for the convenience of description, the pixel unit 115 in the display area AA is schematically illustrated.

Referring to FIG. 10, a planarization layer 306 of the fifth exemplary embodiment of the present disclosure may extend to an end of the substrate 101 to the non-display area NA, similar to the above-described fourth exemplary embodiment, but is not limited thereto.

The organic layer 432 may extend to the non-display area NA.

The cathode 433 may extend to the non-display area NA.

The cathode 433 is spaced apart from an end of the planarization layer 306 with a predetermined distance in the non-display area NA to be in contact with a part of a side surface of the planarization layer 306 in the trench pattern 190, but is not limited thereto.

The cathode 433 may be disposed so as to cover the side surface of the organic layer 432 in the non-display area NA. The organic layer 432 may be disposed to be spaced apart from an end of the cathode 433 with a predetermined distance, but is not limited thereto.

The cathode 433 according to the fifth exemplary embodiment of the present disclosure may be disposed so as to expose a part of the trench pattern 190 and cover the other part, but is not limited thereto.

In the meantime, according to the fifth exemplary embodiment of the present disclosure, a second step relieving layer 540b is disposed so as to be filled in the trench pattern 190.

For example, the second step relieving layer 540b is disposed to be filled in the trench pattern 190 and cover a side surface of the planarization layer 306 and an end portion of the cathode 433 on both sides of the trench pattern 190, but is not limited thereto.

As described above, according to the fifth exemplary embodiment of the present disclosure, the second step relieving layer 540b is formed so as to cover the side surface of the planarization layer 306 and the end portion of the cathode 433 in the trench pattern 190 having a step. Therefore, the permeation of moisture and oxygen into the display device may be more effectively blocked. Accordingly, the lifespan and the reliability of the display device may be further improved.

An inorganic layer 508 may be disposed above the second step relieving layer 540b.

The inorganic layer 508 may extend to the non-display area NA.

The inorganic layer 508 may be disposed to be spaced apart from the end of the planarization layer 306 with a predetermined distance in the non-display area NA to cover the second step relieving layer 540b.

The inorganic layer 508 may be disposed to be in contact with a top surface of the second step relieving layer 540b.

The sealing member 150 and the reinforcement substrate 160 may be disposed above the inorganic layer 508.

In the meantime, the second step relieving layer of the present disclosure may be formed between the planarization layer and the cathode, which will be described in detail with reference to the drawing.

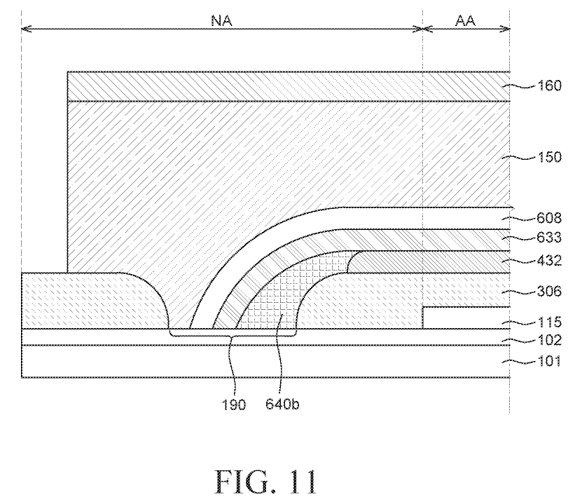

FIG. 11 is a cross-sectional view schematically illustrating a display device according to a sixth exemplary embodiment of the present disclosure.

A sixth exemplary embodiment of the present disclosure of FIG. 11 has the substantially same configuration as the fifth exemplary embodiment of FIG. 10 except that a second step relieving layer 640b is disposed between a planarization layer 306 and a cathode 633, so that a redundant description will be omitted. The same configuration will be denoted by the same reference numeral. Here, the description for the same reference numeral may refer to FIGS. 1 to 10.

FIG. 11 is a cross-sectional view of a non-display area NA in a display device of the sixth exemplary embodiment of the present disclosure and illustrates a cross-section of an upper side, among side portions of the display panel in which the trench pattern 190 is formed. In FIG. 11, for the convenience of description, the pixel unit 115 in the display area AA is schematically illustrated.

Referring to FIG. 11, the planarization layer 306 of the sixth exemplary embodiment of the present disclosure may extend to an end of the substrate 101 to the non-display area NA, similar to the above-described fifth exemplary embodiment, but is not limited thereto.

The organic layer 432 may extend to the non-display area NA.

In the meantime, in the non-display area NA, a partial area of the planarization layer 306 is removed to form a trench pattern 190.

The organic layer 432 is in contact with a top surface of the planarization layer 306 in the trench pattern 190.

In the meantime, according to the sixth exemplary embodiment of the present disclosure, a second step relieving layer 640b is disposed so as to cover a side surface of the planarization layer 306 in the trench pattern 190.

For example, the second step relieving layer 640b covers a side surface of the planarization layer 306 to relieve the step. For example, the second step relieving layer 640b is disposed so as to cover the side surface of the planarization layer 306 in the trench pattern 190. However, the present disclosure is not limited thereto and the second step relieving layer extends to be filled in the trench pattern 190.

The cathode 633 extends to the non-display area NA to be disposed on the second step relieving layer 640b.

The cathode 633 is spaced apart from an end of the planarization layer 306 with a predetermined distance in the non-display area NA to be in contact with a side surface of the second step relieving layer 640b in the trench pattern 190, but is not limited thereto.

For example, in the non-display area NA, the cathode 633 may be disposed so as to cover the organic layer 432 and the second step relieving layer 640b.

The cathode 633 according to the sixth exemplary embodiment of the present disclosure may be disposed so as to expose a part of the trench pattern 190 and cover the other part, but is not limited thereto.

An inorganic layer 608 may be disposed on the cathode 633.

The inorganic layer 608 may extend to the non-display area NA.

The inorganic layer 608 may be disposed to be spaced apart from the end of the planarization layer 306 with a predetermined distance in the non-display area NA to cover an end portion of the cathode 633.

In the meantime, a first step relieving layer of the present disclosure may be disposed in a stripe shape on the sub pixels which are disposed in one direction, which will be described in detail with reference to the drawings.

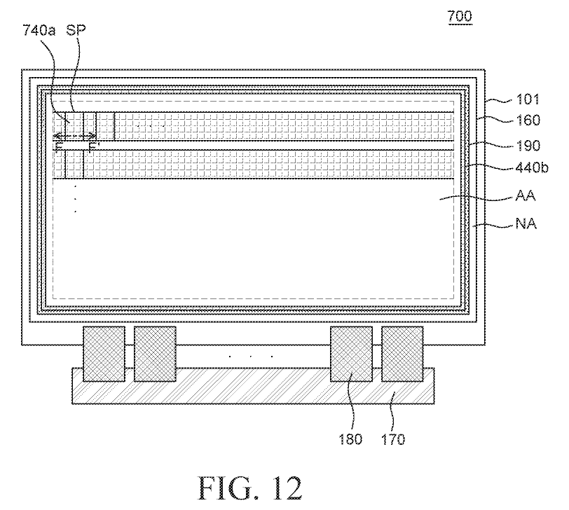

FIG. 12 is a plan view schematically illustrating a display device according to a seventh exemplary embodiment of the present disclosure.

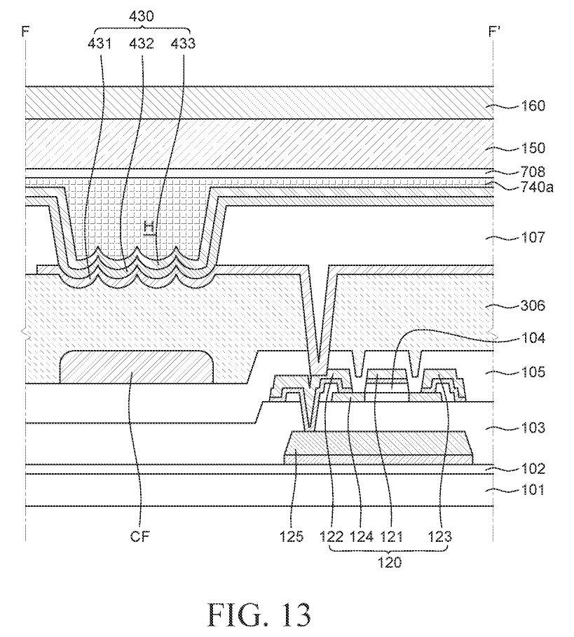

FIG. 13 is a cross-sectional view taken along the line F-F' of FIG. 12.

A seventh exemplary embodiment of the present disclosure of FIGS. 12 and 13 has the substantially same configuration as the fourth exemplary embodiment of FIGS. 7 to 9 except for a placement shape of a first step relieving layer 740a so that a redundant description will be omitted. The same configuration will be denoted by the same reference numeral. Here, the description for the same reference numeral may refer to FIGS. 1 to 11.

FIG. 13 is a cross-sectional view of one sub pixel SP of a display device 700 according to a seventh exemplary embodiment of the present disclosure.

Referring to FIGS. 12 and 13, a planarization layer 306 of the seventh exemplary embodiment of the present disclosure may include a plurality of concave portions formed on the top surface so as to overlap with the color filter CF, similar to the above-described fourth exemplary embodiment.

The plurality of concave portions may have a hemispherical shape or a semi-ellipsoidal shape, but is not limited thereto.

A light emitting diode 430 may be disposed above the planarization layer 306 having the plurality of concave portions. Top surfaces of an anode 431, an organic layer 432, and a cathode 433 may have a plurality of concave portions according to the shape of the concave portion of the planarization layer 306.

A first step relieving layer 740a may be disposed above the light emitting diode 430.

According to the seventh exemplary embodiment of the present disclosure, the first step relieving layer 740a is applied above the light emitting diode 430 having a concave portion to remove the step.

The first step relieving layer 740a of the seventh exemplary embodiment of the present disclosure is disposed above the light emitting diode 430 including a bank hole H. Further, for example, the first step relieving layer 740a is disposed in a stripe shape on the sub pixels SP disposed in one direction.

An inorganic layer 708 may be disposed on the first step relieving layer 740a.

The exemplary embodiments of the present disclosure can also be described as follows:

According to an aspect of the present disclosure, there is provided a display device. The display device includes a substrate which is divided into an display area and a non-display area, a planarization layer disposed above the substrate in the display area and extending into the non-display area, an anode disposed on the planarization layer in the display area, a bank including a bank hole exposing a part of the anode, an organic layer disposed on the bank including the bank hole, a cathode disposed on the organic layer and extending into the non-display area, a first step relieving layer disposed on the cathode and filled in the bank hole, an inorganic layer disposed on the first step relieving layer and extending into the non-display area to cover the cathode and an encapsulation unit disposed above the inorganic layer.

The first step relieving layer may be disposed over the cathode on the entire display area including the bank hole.

The first step relieving layer may be disposed in a stripe shape across a plurality of sub pixels disposed along one direction.

The first step relieving layer may be disposed in a matrix in each sub pixel and in a plan view, the first step relieving layer may have a shape corresponding to a shape of the sub pixel.

The first step relieving layer may partially protrude from a top of the cathode while being filled in the bank hole.

The first step relieving layer may have an upwardly convex shape.

The inorganic layer may be disposed to be in contact with a top surface of the first step relieving layer and the cathode above the bank.

The first step relieving layer may overlap with a color filter therebelow.

The planarization layer may include a plurality of concave portions formed on a top surface to overlap with the color filter and the plurality of concave portions may have a hemispherical shape or a semi-ellipsoidal shape.

Top surfaces of the anode, the organic layer, and the cathode may have a plurality of concave portions corresponding to a shape of the concave portion of the planarization layer.

The display device may further comprise a trench pattern configured by removing a partial area of the planarization layer of the non-display area.

In a plan view, the trench pattern may have a quadrangular frame shape along the non-display area.

The cathode may be disposed to expose a part of the trench pattern and to cover another part of the trench pattern.

The display device may further comprise a second step relieving layer disposed on a side surface of the trench pattern.

The second step relieving layer may be disposed to cover an end portion of the cathode in the trench pattern.

The inorganic layer may extend into the non-display area to cover a top surface and a side surface of the second step relieving layer.

The second step relieving layer may be disposed to cover a side surface of the planarization layer and an end portion of the cathode on both sides of the trench pattern while being filled in the trench pattern.

The second step relieving layer may be disposed to cover a side surface of the planarization layer in the trench pattern and the cathode may extend to the non-display area to be disposed on the second step relieving layer.

The first step relieving layer and the second step relieving layer may be formed of a thermosetting resin or an UV curable resin.

The encapsulation unit may include a sealing member disposed above the inorganic layer and a reinforcement substrate disposed on the sealing member, and the sealing member and the reinforcement substrate may extend into the non-display area to cover a part of the planarization layer and the inorganic layer.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

What is claimed is:

1. A display device, comprising:
a substrate which is divided into a display area and a non-display area;
a planarization layer disposed above the substrate in the display area and extending into the non-display area;
an anode disposed on the planarization layer in the display area;
a bank comprising a bank hole exposing a part of the anode;
an organic layer disposed on the bank comprising the bank hole;
a cathode disposed on the organic layer and extending into the non-display area;
a first step relieving layer disposed on the cathode and filled in the bank hole;
an inorganic layer disposed on the first step relieving layer and extending into the non-display area to cover the cathode; and
an encapsulation unit disposed above the inorganic layer.

2. The display device according to claim 1, wherein the first step relieving layer is disposed on the cathode over an entire display area including the bank hole.

3. The display device according to claim 1, wherein the first step relieving layer is disposed in a stripe shape across a plurality of sub pixels disposed along one direction.

4. The display device according to claim 1, wherein the first step relieving layer is disposed in a matrix in each sub pixel, and wherein, in a plan view, the first step relieving layer has a shape corresponding to a shape of the sub pixel.

5. The display device according to claim 4, wherein the first step relieving layer partially protrudes from a top of the cathode while being filled in the bank hole.

6. The display device according to claim 5, wherein the first step relieving layer has an upwardly convex shape.

7. The display device according to claim 4, wherein the inorganic layer is disposed to be in contact with a top surface of the first step relieving layer and the cathode above the bank.

8. The display device according to claim 1, wherein the first step relieving layer overlaps with a color filter therebelow.

9. The display device according to claim 8, wherein the planarization layer comprises a plurality of concave portions formed on a top surface to overlap with the color filter, and wherein the plurality of concave portions has a hemispherical shape or a semi-ellipsoidal shape.

10. The display device according to claim 9, wherein top surfaces of the anode, the organic layer, and the cathode comprise a plurality of concave portions corresponding to a shape of the concave portion of the planarization layer.

11. The display device according to claim 1, further comprising:
a trench pattern configured by removing a partial area of the planarization layer of the non-display area.

12. The display device according to claim 11, wherein in a plan view, the trench pattern has a quadrangular frame shape along the non-display area.

13. The display device according to claim 11, wherein the cathode is disposed to expose a part of the trench pattern and to cover another part of the trench pattern.

14. The display device according to claim 13, further comprising:
a second step relieving layer disposed on a side surface of the trench pattern.

15. The display device according to claim 14, wherein the second step relieving layer is disposed to cover an end portion of the cathode in the trench pattern.

16. The display device according to claim 14, wherein the inorganic layer extends into the non-display area to cover a top surface and a side surface of the second step relieving layer.

17. The display device according to claim 14, wherein the second step relieving layer is disposed to cover a side surface of the planarization layer and end portions of the cathode on both sides of the trench pattern while being filled in the trench pattern.

18. The display device according to claim 14, wherein the second step relieving layer is disposed to cover a side surface of the planarization layer in the trench pattern and the cathode extends to the non-display area to be disposed on the second step relieving layer.

19. The display device according to claim 14, wherein the first step relieving layer and the second step relieving layer are formed of a thermosetting resin or a UV curable resin.

20. The display device according to claim 1, wherein the encapsulation unit comprises:
a sealing member disposed above the inorganic layer; and
a reinforcement substrate disposed on the sealing member,
wherein the sealing member and the reinforcement substrate extend into the non-display area to cover a part of the planarization layer and the inorganic layer.
